(19) United States
(12) Patent Application Publication
(10) Pub. No.: US 2025/0300144 A1
(43) Pub. Date: Sep. 25, 2025

(54) SYSTEM AND METHODS FOR EMBEDDED MULTI-STACK PACKAGES

(71) Applicant: Samsung Electronics Co., Ltd., Suwon-si (KR)

(72) Inventors: Yan LI, Morgan Hill, CA (US); WooPoung KIM, San Jose, CA (US)

(21) Appl. No.: 19/074,313

(22) Filed: Mar. 7, 2025

Related U.S. Application Data
(60) Provisional application No. 63/567,879, filed on Mar. 20, 2024.

(51) Int. Cl. H01L 25/10; H01L 21/48; H01L 23/00; H01L 23/14; H01L 23/15; H01L 23/367; H01L 23/473; H01L 23/538; H01L 25/065; H01L 25/16; H10B 80/00; H10D 80/30

(52) U.S. Cl. CPC H01L 25/105; H01L 21/485; H01L 21/486; H01L 21/4882; H01L 23/147; H01L 23/15; H01L 23/3677; H01L 23/473; H01L 23/5385; H01L 23/5386; H01L 25/0655; H01L 25/16; H10D 80/30; H01L 23/3675; H01L 24/08; H01L 24/16; H01L 24/32; H01L 24/73; H01L 2224/08225; H01L 2224/16225; H01L 2224/32225; H01L 2224/73204; H01L 2225/06517; H01L 2225/06548; H01L 2225/06589; H01L 2225/1023; H01L 2225/1094; H01L 2924/1815; H10B 80/00

(57) ABSTRACT

Disclosed herein are methods, systems and devices including a substrate having a first attachment location and a second attachment location, a first multi-device package located within the first attachment location, a first embedded circuit located within the second attachment location, and a first compute device located on the substrate and at least partially over the first attachment location and the second attachment location.

### CROSS-REFERENCE TO RELATED APPLICATION

This application claims the priority benefit under 35 U.S.C. § 119 (e) of U.S. Provisional Patent Application Ser. No. 63/567,879 filed on Mar. 20, 2024, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a technique for packaging embedded multi-stack packages.

### BACKGROUND

Semiconductor devices may connect to additional devices and circuitry on different substrates. Forming connections between substrates can provide increased computation. However, forming connections between substrates can cause complications. Packaging describes the general method for connecting and integrating multiple computational components together in an integrated unit, and may involve multiple different types of integrated circuits on multiple substrates which may combine into a single unit. Packaging may also describe the method for which multiple computational components within a single unit are protected by the use of various techniques to provide thermal, physical and electrical protection. Background concepts discussed herein are for informational purposes only and are not intended to limit the present disclosure. Nor should the background or field described herein be intended to limit the disclosure herein to a particular use or concept.

### SUMMARY

An example embodiment provides a device including a substrate having a first attachment location and a second attachment location, a first multi-device package located within the first attachment location, a first embedded circuit located within the second attachment location, and a first compute device located on the substrate and at least partially over the first attachment location and the second attachment location. In some embodiments, a second compute device may be located on the substrate at least partially over the second attachment location and is electrically connected to the first compute device by the first embedded circuit. In some embodiments, the first multi-device package includes at least one of a memory device and a processing device. In some embodiments, a redistribution layer is between the first compute device and the first multi-device package. In some embodiments, the substrate is at least one of glass and silicon. In some embodiments, the first compute device is an integrated circuit. In some embodiments, a fluid cooling channel is formed within the substrate, a heat conduit is formed between the first attachment location and a surface of the substrate, and the heat conduit may thermally couple the first multi-device package to the fluid cooling channel. In some embodiments, a third attachment location may have a second multi-device package within, and the second multi-device package may be coupled to the first multi-device package via the first embedded circuit.

An example embodiment provides a system including a substrate having a first side and a second side opposite the first side, the first side having a first attachment location and a second attachment location, a first multi-device package may be at least partially within the first attachment location, a first connecting element may be at least partially within the second attachment location, a first compute device may be located on the first side of the substrate, and a first heat conduit may be within the substrate and extend from the second side to the first attachment location. In some embodiments, a second compute device is located on the first side of the substrate and is coupled to the first compute device via the first connecting element at least partially within the second attachment location. In some embodiments, an attachment layer may be between the first heat conduit and the first multi-device package. In some embodiments, a second heat conduit within the substrate may extend from the second side to the second attachment location, and an attachment layer may be between the second heat conduit and the first connecting element. In some embodiments, a fluid cooling channel within the substate may be thermally coupled to the first heat conduit. In some embodiments, a redistribution layer may be between the first compute device and the first multi-device package. In some embodiments, the first compute device is placed at least partially over the first attachment location and the second attachment location.

An example embodiment provides a method including forming a first attachment location and a second attachment location within a first side of a substrate, placing a first multi-device package at least partially within the first attachment location, placing a first embedded circuit at least partially within the second attachment location, forming a redistribution layer on the first side of the substrate, placing a first compute device on the redistribution layer and electrically connected to the first multi-device package and the first embedded circuit, and placing a second compute device on the redistribution layer and electrically coupling the second compute device to the first compute device via the first embedded circuit. In some embodiments, the substrate may be prepared by forming at least one of a heat conduit, a liquid cooling channel and a though-substrate via. In some embodiments, a conductive lid may be placed over at least one of the first compute device, the second compute device, and the redistribution layer. In some embodiments, the first multi-device package includes at least one of a processing device and a memory device. In some embodiments, forming the first attachment location and the second attachment location within the first side of the substrate includes laser milling a glass substrate.

### BRIEF DESCRIPTION OF THE DRAWING

In the following section, the aspects of the subject matter disclosed herein will be described with reference to exemplary embodiments illustrated in the figures, in which:

FIG. 1 depicts a cross-section view of an example embodiment of a packaging structure according to various embodiments of the subject matter disclosed herein;

FIG. 2A depicts an enlarged cross-section view of an example embodiment of a packaging structure according to various embodiments of the subject matter disclosed herein;

FIG. 2B depicts a plan view of an example embodiment of a packaging structure according to various embodiments of the subject matter disclosed herein;

FIG. 3A depicts a cross-section view of an example embodiment of a packaging structure at a first time according to various embodiments of the subject matter disclosed herein;

FIG. 3B depicts a cross-section view of an example embodiment of a packaging structure at a second time according to various embodiments of the subject matter disclosed herein;

FIG. 3C depicts a cross-section view of an example embodiment of a packaging structure at a third time according to various embodiments of the subject matter disclosed herein;

FIG. 3D depicts a cross-section view of an example embodiment of a packaging structure at a fourth time according to various embodiments of the subject matter disclosed herein;

FIG. 3E depicts a cross-section view of an example embodiment of a packaging structure at a fifth time according to various embodiments of the subject matter disclosed herein;

FIG. 3F depicts a cross-section view of an example embodiment of a packaging structure at a sixth time according to various embodiments of the subject matter disclosed herein;

FIG. 3G depicts a cross-section view of an example embodiment of a packaging structure at a seventh time according to various embodiments of the subject matter disclosed herein;

FIG. 3H depicts a cross-section view of an example embodiment of a packaging structure at an eighth time according to various embodiments of the subject matter disclosed herein;

FIG. 4 depicts an example embodiment of a method of forming a package structure according to various embodiments of the subject matter disclosed herein;

FIG. 5 depicts a cross-section view of an example embodiment of a packaging structure according to various embodiments of the subject matter disclosed herein;

FIG. 6 depicts a cross-section view of an example embodiment of a packaging structure according to various embodiments of the subject matter disclosed herein;

FIG. 7 depicts a cross-section view of an example embodiment of a packaging structure according to various embodiments of the subject matter disclosed herein; and

FIG. 8 depicts an example embodiment of a method of forming a package structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Integrated Chip,” “First Substrate,” “PIC” etc.) may be interchangeably used with a corresponding non-capitalized version (e.g., “integrated chip,” “first substrate,” “pic,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein compute devices, may refer to a wide variety of integrated circuits using electrical components. In some embodiments, compute devices may include central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), auxiliary processing units (XPUs), graphical processing units (GPUs), other forms of auxiliary processing units (xPU), artificial intelligence (AI) chips, high bandwidth memory (HBM) interfaces, and other application-specific integrated circuits (ASIC). In some embodiments, a combination of circuits may be present on a substrate. In some embodiments, compute devices may be referred to in terms such as microchips, microcontrollers, silicon chips. As used herein, an XPU may refer to an auxiliary processing unit designed to perform specialized or dedicated processing optimized for conducting specific tasks more efficiently than a general processing unit such as a CPU, and may be also referred to as a data processing unit (DPU), infrastructure processing unit (IPU), function accelerator card (FAC), network attached processing unit (NAPU).

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2 W) or die-to-wafer bonding (D2 W). In some embodiments, a packaged chip may contain multiple substrates.

As used herein packaging refers to a process of forming interconnections between substrates. In some embodiments, the interconnections may be between direct surfaces and involve W2 W, D2D, and D2 W bonding. In other embodiments, techniques including wire bonding and other forms of indirect bonding may be performed alone or in combination with W2 W, D2D, and D2 W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs), through-glass vias (TGVs) or other forms of through-chip vias where one or more substrates may be electrically connected using a via traveling through an interposer such as another substrate or chip. In some embodiments, an interconnection may be formed using connections on a surface of a substrate, such as a pad, and may use additional materials between the pads such as solder to form an interconnection.

In some embodiments, bonding between substrates may involve bonding between metals, or metal-metal bonding. In some embodiments, bonding between substrates may involve bonding between dielectric materials, or dielectric-dielectric bonding. In some embodiments, bonding between substrates may involve both metal-metal and dielectric-dielectric bonding, known as hybrid bonding. A hybrid bonding technique may be used to provide additional connections between opposing surfaces, allowing both dielectric and conductive surfaces to bond, and may increase the mechanical strength of the resulting structure.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein, a device stack or stack of devices may refer to a combination of memory and supporting circuit architecture, for example, chiplets and dies containing individual memory elements, supporting processing units, input output (I/O) circuitry, and other forms of integrated chips. As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. A core may refer to a single-unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit. As used herein, high bandwidth memory or HBM, may refer to a chip structure including one or more HBM modules. In some embodiments, the HBM may be manufactured by an advanced silicon node process.

As used herein, a connecting element refers to a substrate, die, or other material having one or more conductive pathways able to form connection between one or more semiconductor devices, as well as substrates, interposers, or other package structures. A connecting element may include one or more traces, the traces forming a connection pathway along the connecting element between one or more devices coupled to the connecting element. An embedded connecting element, as used herein, may refer to a connecting element in a layer within a semiconductor package, and may be used interchangeably with connecting element. An active connecting element may refer to a connecting element featuring additional features beyond connections, such as transistors, vias, and other circuit components. As used herein, a connecting element may be referred to as a connector, a bridge, or a bridge arch; an active connecting element may be referred to as an active bridge, an active bridge arch, or an active connector; and an embedded connecting element may be referred to as an embedded bridge, an embedded bridge arch, or an embedded connector.

Disclosed herein are various embodiments of systems, methods and devices of packaging architecture using multi-device packages embedded within a core substrate. The packaging architecture may be formed in three-dimensions and couple one or more multi-device packages on a supporting substrate. The supporting substrate, also referred to as the core substrate, may be a glass core substrate, a silicon substrate, or a substrate formed of any appropriate substrate, including substrates made from organic materials, silicon, silicon core substrates, as well as glass substrates. In some embodiments, within the supporting substrate additional devices and components may be formed, for example additional compute devices, voltage regulation modules, capacitors, integrated stack capacitors, logic devices, routing, power delivery and communication routing may be formed on or within the supporting substrate.

A multi-device package includes one or more compute devices formed on a support base. The support base may include one or more layers to transmit electrical signals and power between the support base and one or more compute devices positioned on the support base. In some embodiments, the support base may include circuitry to provide one or more of routing, logic, and buffering to the one or more compute devices on the support base. In some embodiments, the one or more compute devices may take the form of one or more device stacks including multiple compute devices.

One or more multi-device packages may be formed within the supporting substrate. A connecting element, also referred to as a bridge, may be used to couple compute devices between multiple support bases of several multi-device package. In some embodiments, the connecting element may be formed within the supporting substrate, while in other embodiments, the connecting element may be formed on top of the supporting substrate. In some embodiments, the connecting element may take the form of one or more redistribution layers. The one or more multi-device packages may be coupled to each other, as well as additional circuitry embedded within the supporting substrate or placed thereupon, including connecting elements, capacitors, voltage regulators, and surface compute devices.

Upon the supporting substrate, in some embodiments one or more surface compute devices may be located, and may be coupled to one or more multi-device packages. The one or more surface compute devices may take the form of application specific integrated circuits, or ASIC, as well as any other suitable circuitry. In some embodiments, the one or more surface compute devices may offload functions of the multi-device packages and reduce the computational burden on the multi-device packages. In some embodiments, a thermal conductive lid made of a heat transmitting material, such as copper or another suitable metal, may be formed over the one or more surface compute devices.

In some embodiments, one or more additional heat conducting features may be formed on or within the supporting substrate in addition to the lid. In some embodiments, a fluid cooling channel may be formed within the supporting substrate allowing a fluid coolant to transfer heat from devices embedded within the supporting substrate. In some embodiments, one or more heat conduits may be formed within the supporting substrate and may thermally couple devices within the supporting substrate to a surface of the supporting substrate. In some embodiments, one or more heat conduits may thermally couple devices within the supporting substrate to a fluid cooling channel.

In some embodiments, one or more supporting substrates may be placed upon each other, and may share the same thermal conductive lid and surface compute devices. In some embodiments, a supporting substrate may have a thermal conductive lid and surface compute devices formed on a top surface. In some embodiments, the supporting substrate may have a thermal conductive lid and surface compute devices formed on a bottom surface. In some embodiments, the supporting substrate may have a thermal conductive lid and surface compute devices formed on both the bottom surface and top surface.

Disclosed herein is a method or forming package, including preparing a supporting substrate with heat conduits, trans-substrate vias, and fluid cooling channels. One or more cavities, also referred to as attachment locations, may be formed within the supporting substrate. The one or more cavities may be formed within a first surface of the supporting substrate, and may be formed so that a heat conduit on a second surface of the supporting substrate, opposite the first surface, may be exposed. Within the one or more cavities, die attachment films may be formed to allow the multi-device packages and other embedded elements to be attached to the supporting substrate. One or more redistribution layers may be then formed on the supporting substrate, including over the multi-device packages and other embedded elements. Upon a redistribution layer, the one or more surface compute devices are attached and coupled to the embedded multi-device packages. A thermal conductive lid may then be placed upon the supporting substrate.

As used herein, a redistribution layer may refer to one or more individual layers including one or more conductive materials such as a series of pads, bumps, vias, through-vias, traces, and other forms of connection for redistributing signals across the layer. In some embodiments, redistribution layers may be used to connect different components spread across a device package, allowing signals and power to transfer laterally across the redistribution layers. Redistribution layers may allow for indirect coupling between connections on adjacent layers by providing additional routes for the signals to transfer laterally as well as vertically.

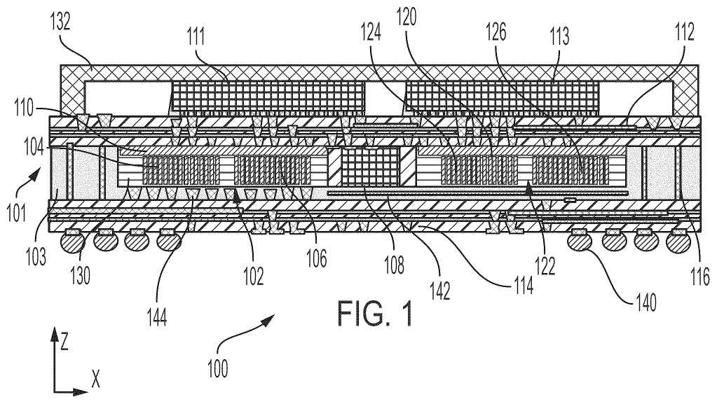

FIG. 1A depicts a cross-sectional view of an exemplary embodiment of a first device package architecture 100. The first device package architecture 100, which may be referred to as an embedded stack, includes a supporting substrate 101 with a first multi-device package 102 and a second multi-device package 122 placed within the supporting substrate 101. The first multi-device package 102 includes a first compute device 104, a second compute device 106 within a first encapsulation layer 130 and a first support base 110. The supporting substrate 101 includes a core substrate 103 with an upper RDL 112 formed on top of the core substrate 103 and a lower RDL 114 formed on the bottom of the core substrate 103. The first support base 110 may couple to the supporting substrate 101 via the upper RDL 112. A first auxiliary compute device 111 and a second surface compute device 113 may be placed on top of supporting substrate 101, and coupled to the first multi-device package 102 via the upper RDL 112. One or more TSVs 116 may couple the upper RDL 112 to the lower RDL 114. The second multi-device package 122 may similarly to the first multi-device package 102 include a third compute device 124, a fourth compute device 126 within the first encapsulation layer 130 and a second support base 120. The second support base 120 may be made similar to the first support base 110, and likewise the third compute device 124 and the fourth compute device 126 may be made similar to the first compute device 104 and the second compute device 106.

In some embodiments, the compute devices including the first compute device 104, the second compute device 106, the third compute device 124, and the fourth compute device 126 may include a die, a core, or chiplet, or any other suitable form of circuit. As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. In some embodiments, the compute devices may be various forms of memory including DRAM, SRAM, and other forms of memory. In some embodiments, the devices may include a core device, for example a processor, processing device, or other form of microcontroller to act as a controller. A core may refer to a single-unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit. In some embodiments, a single compute device may be used, while in other embodiments, additional compute devices may be added, for example 4, 6, 8, 16 or 32 compute devices may be added. In some embodiments, each compute device may be a single device, while in other embodiments, each compute device may be multiple devices stacked on top of each other, such as in HBM.

In some embodiments, the compute devices of the first multi-device package 102 and the second multi-device package 122 may be the same type of devices, also referred to as having the same device composition. In other embodiments, the first multi-device package 102 and the second multi-device package 122 may differ in device composition. For example, the first multi-device package 102 and the second multi-device package 122 may differ in the number of processing units and memory devices within the component compute devices.

Additionally, the first encapsulation layer 130 may surround the first compute device 104 and the second compute device 106, and at least a portion of the first support base 110. A second portion of the first encapsulation layer 130 may likewise surround the third compute device 124, the fourth compute device 126 and at least a portion of the second support base 120. The first encapsulation layer 130 may be a dielectric material such as silicon nitride (Si₃N₄) or silicon dioxide (SiO₂). In some embodiments, the first encapsulation layer 130 may provide mechanical support, such as holding the devices in places, as well as may provide electrical isolation, and may provide a thermal path for heat from the compute devices to transfer via. In some embodiments, the first encapsulation layer 130 may be an epoxy molding compound or resin. The first encapsulation layer 130 may, in some embodiments, comprise one or more encapsulation layers, and may include individual encapsulation layers to encapsulate the first compute device 104, the second compute device 106, the third compute device 124, and the fourth compute device 126.

The upper RDL 112 may electrically couple to the first multi-device package 102, the second multi-device package 122, and the first embedded circuit 108, as well as to one or more TSVs 116 within the supporting substrate 101. In some embodiments, the first auxiliary compute device 111 and the second surface compute device 113 may be placed upon the upper RDL 112 and coupled directly to the first multi-device package 102 and the second multi-device package 122. In some embodiments, the first auxiliary compute device 111 and the second surface compute device 113 may take the form of one or more ASIC devices. In some embodiments, the first auxiliary compute device 111 and the second surface compute device 113 may provide for additional computational support for the first multi-device package 102 and the second multi-device package 122, allowing the first multi-device package 102 and the second multi-device package 122 to offload functions such as voltage regulation, routing functions, and any other appropriate function.

In some embodiments, the first multi-device package 102 and the second multi-device package 122 may be coupled directly using the upper RDL 112, while in other embodiments, the first embedded circuit 108 may take the form of a connecting element such as a bridge, providing a route between the first multi-device package 102 and the second multi-device package 122. In some embodiments, the first embedded circuit 108 may take the form of an active bridge, including additional circuitry such as logic, capacitors, and voltage regulation modules or VRMS, to actively modulate and route signals to and from the first multi-device package 102 and the second multi-device package 122. In other embodiments where the first multi-device package 102 and the second multi-device package 122 are coupled directly using the upper RDL 112, the first embedded circuit 108 may take the form of additional circuitry such as integrated stack capacitors, VRMS, and other circuits to provide support to the first device package architecture 100.

The one or more TSVs 116 within the supporting substrate 101 may electrically couple the upper RDL 112 to one or more elements positioned on or within the supporting substrate 101, as well as electrically couple the upper RDL 112 to the lower RDL 114 on the bottom of the supporting substrate 101. The lower RDL 114 may provide one or more layers including a series of pads, bumps, vias, through-vias, traces, and other forms of connection for redistributing signals from electrical connections from the supporting substrate 101 to the one or more TSVs 116, the first compute device 104, the second compute device 106, and the first embedded circuit 108.

In some embodiments, the supporting substrate 101 may be placed on a further substrate or card. The interconnection between the supporting substrate 101 and a further substrate may include conductive materials forming substrate interconnections 140 to electrically couple the supporting substrate 101 to the further substrate including pads, bumps, microbumps, pillars, balls, and other forms such as C4 bumps, alone or in combination. In some embodiments, a bonding layer between the supporting substrate 101 and the further substrate may include a dielectric material or an adhesive, like underfill material, to provide additional strength and connection between the supporting substrate 101 and the further substrate. In some embodiments, the interconnection may provide a metallic bonding between the supporting substrate 101 and the further substrate, a dielectric bonding between the supporting substrate 101 and the further substrate, or in some embodiments a hybrid bonding between the supporting substrate 101 and the further substrate. In some embodiments, the interconnection may bond directly with the lower RDL 114, while in other embodiments, intermediate layers may between the interconnection and the lower RDL 114.

Additionally, the supporting substrate 101 may contain one or more fluid cooling channels 142 and one or more heat conduits 144. In some embodiments, the one or more heat conduits 144 may be referred to as thermal vias. In some embodiments, the one or more fluid cooling channels 142 may comprise a channel formed within the supporting substrate 101 for the passage of a fluid. In some embodiments, the fluid used within the one or more fluid cooling channels 142 may be a gas, such as air, nitrogen, argon, or other gas suitable for use within a semiconductor substrate. In some embodiments, the fluid used within the one or more fluid cooling channels 142 may be a liquid, such as water, aqueous solution, alcohols, glycol, and combinations thereof. In some embodiments, the one or more fluid cooling channels 142 may be formed directly in the supporting substrate 101, while in other embodiments, the one or more fluid cooling channels 142 may include one or more layers between the supporting substrate 101 and the fluid of the one or more fluid cooling channels 142. In some embodiments, the one or more layers may include a material such as a metal, ceramic, or other material to provide thermally conductive pathway between the fluid and the supporting substrate 101. In some embodiments, the one or more layers may include a material layer to provide encapsulation and protection from corrosion or other damage from a fluid.

In some embodiments, the one or more heat conduits 144 may be formed in the core substrate 103 and extend from a cavity containing the first embedded circuit 108 to a backside surface. In some embodiments, the one or more heat conduits 144 may be one or more through-vias, such as a TSV or TGV, depending on the material of the core substrate 103. In some embodiments, the one or more heat conduits 144 may include a thermal conductive material within a through-via, such as metal like copper, silver, or aluminum, as well as additional materials suitable for use with a semiconductor process such as aluminum nitride, silicon carbide, or any other suitable thermal conductive material such as diamond, and combinations thereof. In some embodiments, the one or more heat conduits 144 may couple to additional structures for regulating heat, such as a thermal electric device, heat sinks, cooling pad, or other suitable structure. Additionally, in some embodiments, the one or more heat conduits 144 may couple with the one or more fluid cooling channels 142. In some embodiments, the one or more heat conduits 144 may contact the first embedded circuit 108, the first multi-device package 102 or the second multi-device package 122, while in other embodiments an attachment layer may be between the one or more heat conduits 144 and the first embedded circuit 108, the first multi-device package 102 or the second multi-device package 122.

In some embodiments, the one or more heat conduits 144 may conduct heat into a fluid of the one or more fluid cooling channels 142, and heat may be transferred away from the one or more heat conduits 144 using convective heat transfer, conductive heat transfer, or a combination thereof. In some embodiments, the fluid may be actively sent, with a mechanism such as a pump or a fan, or any other suitable method of fluid transfer, to force the flow of the fluid, while in other embodiments, the fluid path may be shaped to allow passive flow of the fluid, or use any other mechanism for passive transport, for example, using a fluid experiencing a phase change. In some embodiments, the one or more fluid cooling channels 142 may be part of a closed loop cooling system, while in other embodiments, the one or more fluid cooling channels 142 may be part of an open loop system, while in yet other embodiments, the one or more fluid cooling channels 142 may transfer between an open loop and closed loop system. In some embodiments, a heat sink, heat exchanger, expander, compressor, cooling pad, thermal cooler, or any other suitable form of cooling, and combinations thereof may be coupled to the one or more fluid cooling channels 142 to provide cooling for the fluid of the one or more fluid cooling channels 142. In some embodiments, the heat transferred via the one or more fluid cooling channels 142 may be transferred to another fluid, or may be conducted to another surface. In some embodiments, a thermal dissipation structure may be used to provide cooling using a combination of radiative, conductive, and convective heat transfer. In some embodiments, a single one of the one or more fluid cooling channels 142 may provide cooling to all of the elements embedded within the supporting substrate 101, while in other embodiments, each element may have a separate one of the one or more fluid cooling channels 142. In some embodiments, the one or more fluid cooling channels 142 may have one of the one or more fluid cooling channels 142 coupled to all of the elements embedded within the supporting substrate 101, while in other embodiments, each element embedded within the one or more fluid cooling channels 142 may have a separate one of the one or more fluid cooling channels 142 to provide relief.

In some embodiments, a conductive lid 132, may be formed over the top of the first device package architecture 100, with the conductive lid 132 coupled to the supporting substrate 101 and providing thermal, mechanical, and electrical protection for the first device package architecture 100. In some embodiments, the conductive lid 132 may be coupled with one or more of the first surface compute device 111 and the second surface compute device 113, either directly or with an intermediate layer such as a thermal paste between the conductive lid 132 and the first surface compute device 111 and the second surface compute device 113. In some embodiments, an additional material may be inserted into any gaps formed by the conductive lid 132, such as a thermal paste. In some embodiments, the conductive lid 132 may form a thermal conductive pathway for heat to transfer from the component devices placed on or within the supporting substrate 101 to the surrounding environment. In some embodiments, the conductive lid 132 may include one or more heat dissipating structures, for example fins, heat sinks, as well as fans, or any other suitable thermal transfer method.

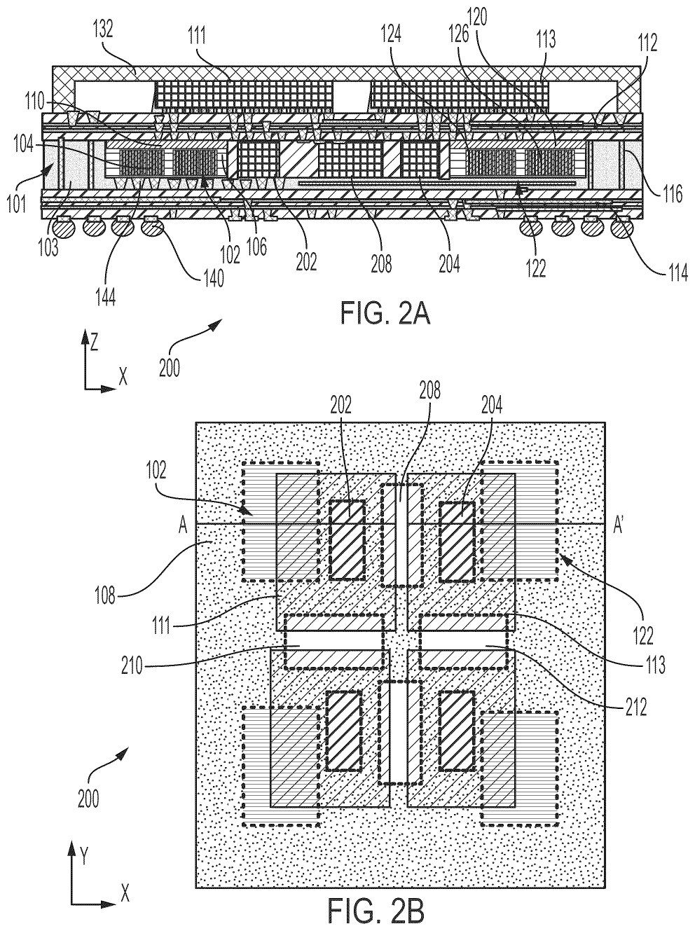

FIG. 2A depicts a cross-sectional view of an example embodiment of a second device package architecture 200, which differs from the first device package architecture 100 by including a second embedded circuit 202, a third embedded circuit 204 and a first connecting element 208 in the supporting substrate 101. While in the first device package architecture 100, the first embedded circuit 108 may act as a connecting element, in the second device package architecture 200, the potential functions of the first embedded circuit 108 may be split across the second embedded circuit 202, the third embedded circuit 204 and the first connecting element 208. That is, in the second device package architecture 200, the first connecting element 208 may act as logic and routing to couple the first multi-device package 102 and the second multi-device package 122. In addition, the second embedded circuit 202 and the third embedded circuit 204 may provide functions such as voltage regulation, capacitance, power conditioning, and other supporting tasks. The first connecting element 208 may also act as either a passive bridge providing routing pathways between the first multi-device package 102 and the second multi-device package 122 alone, or may be an active bridge with additional functions such as logic for routing between the first multi-device package 102 and the second multi-device package 122. The first connecting element 208 may comprise a semiconductor material such as silicon, although in other embodiments different semiconductors materials such as germanium may be used. The first connecting element 208 may include embedded routes which may be provided as traces, wires, buried lines, or any other known suitable method for providing a signal connection on or within a semiconductor device. In some embodiments, the first connecting element 208 may include additional circuit components for routing, monitoring, and protecting signals sent via the first connecting element 208, and may form a logic chip. The first connecting element 208 may provide for electrical signals to transfer between the first multi-device package 102 and the second multi-device package 122, as well as electrical signals between the first surface compute device 111 and the second surface compute device 113.

In some embodiments, one or more additional TSV may couple one or more of the second embedded circuit 202, the third embedded circuit 204 and the first connecting element 208 to the first surface compute device 111 and the second surface compute device 113, and connect via the upper RDL 112 or the lower RDL 114.

FIG. 2B depicts a plan view of the second device package architecture 200, showing the first multi-device package 102 and the second multi-device package 122 embedded on the supporting substrate 101 and partially overlapping the first surface compute device 111 and the second surface compute device 113. The view of FIG. 2B provides a plan view in the X-Y direction, while FIG. 2A is along the line A-A′ within the X-Z direction.

As shown in FIG. 2B, the first connecting element 208 may provide the connection between the devices placed on and within the supporting substrate 101. The first connecting element 208 may thus couple via the upper RDL 112 the first surface compute device 111 and the second surface compute device 113, with the first surface compute device 111 also coupled with the first multi-device package 102 and the second surface compute device 113 coupled with the second multi-device package 122. In addition, the connection scheme may be repeated with additional devices. FIG. 2B shows a second row of multi-device packages and surface compute devices coupled with the first row by a second connecting element 210 and a third connecting element 212, with the second row repeating the elements of the first row. While FIG. 2B shows two rows, in some embodiments, additional rows may be similarly coupled to the first or second row, with three, four, five or more rows being possible. In addition, in some embodiments, additional columns may be added, to create 2×2, 3×3, 4×4 and other similar arrangements.

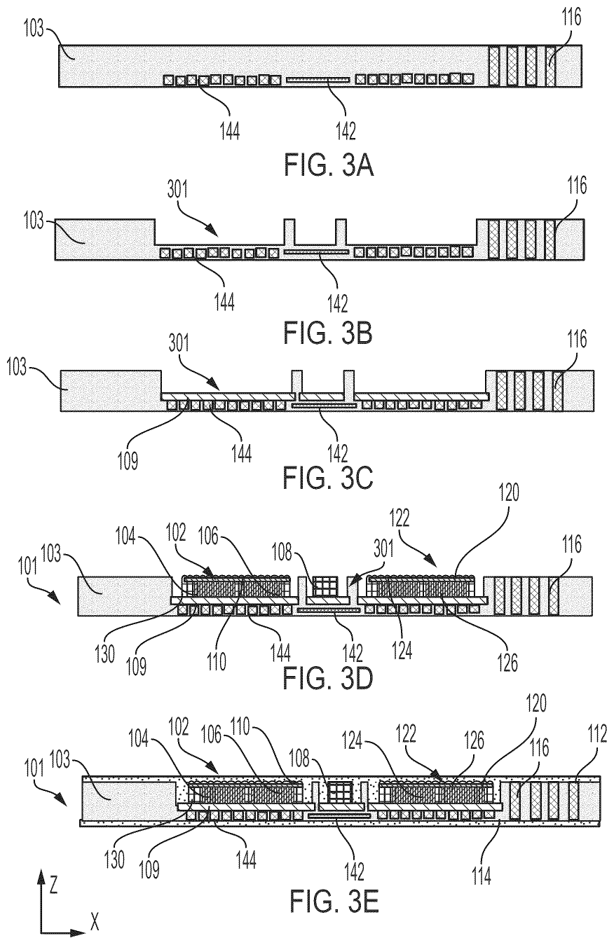

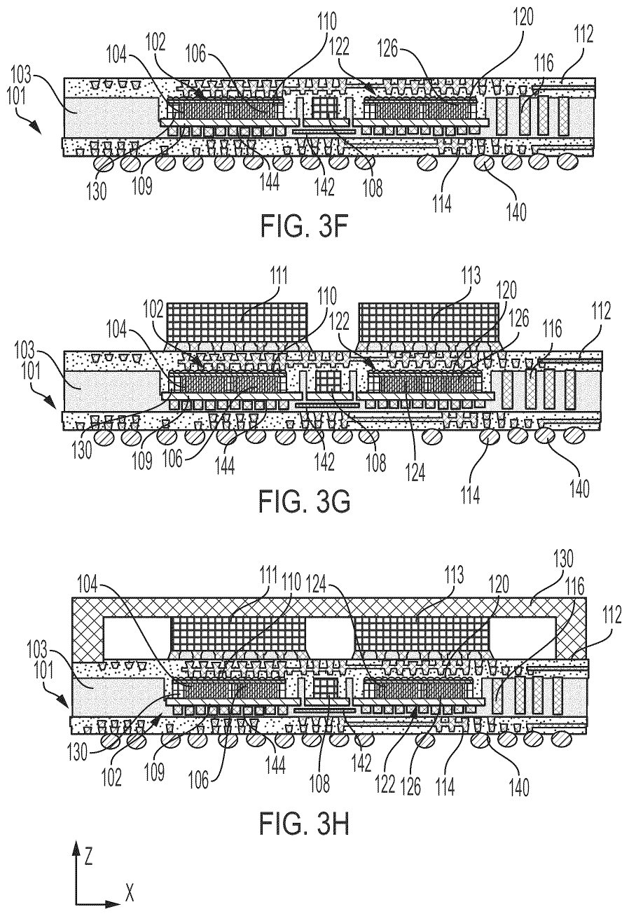

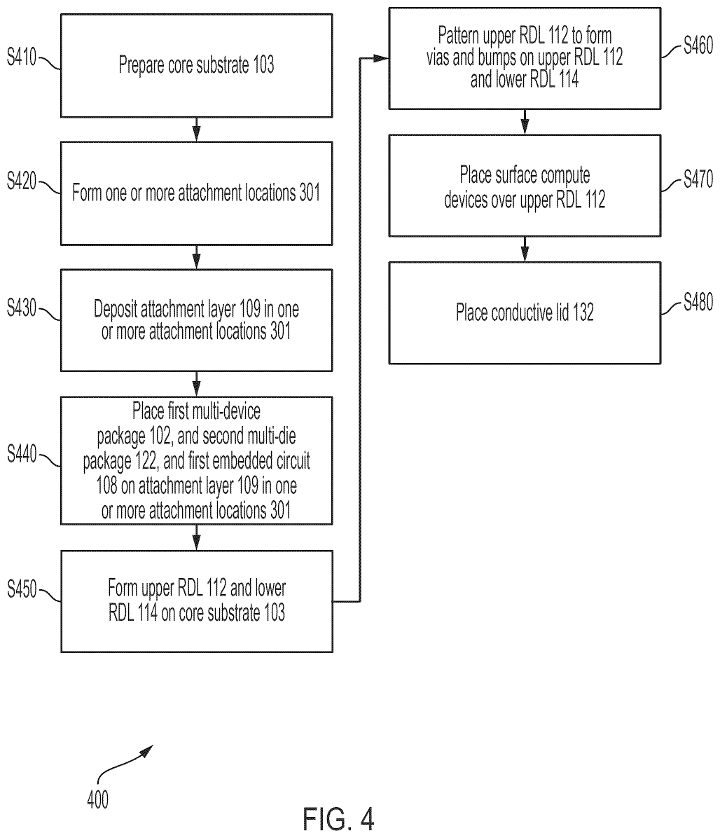

FIGS. 3A-3H depict an illustrative embodiment of a process of forming a device package architecture such as the first device package architecture 100, or any other device package architectures shown herein. FIG. 4 depicts an example embodiment of a process 400 for forming a device package assembly corresponding to the illustrative embodiment of FIGS. 3A-3H.

FIG. 3A depicts S410 in the process of FIG. 3 where the core substrate 103 is prepared. The core substrate 103 may be formed of glass or a semiconductor such as silicon, or a combination thereof. In some embodiments, the core substrate 103 may have the one or more through-vias formed within, the one or more TSVs 116 extending between a first side and a second side of the core substrate 103. In some embodiments, the one or more TSVs 116 may be formed using drilling, laser milling, etching, or any other suitable process, and combinations thereof. In some embodiments, the one or more TSVs 116 may include a conductive material formed within the one or more TSVs 116, such as a metal plug, and may include materials such as copper, aluminum, titanium, tungsten, and combinations thereof. In some embodiments, the conductive material may be formed by a physical vapor deposition (PVD) process, a chemical vapor deposition (CVD) process, an atomic layer deposition (ALD) process, electrowetting, electroplating, or any other suitable technique. In some embodiments, one or more materials may be deposited to form a liner layer prior to bulk deposition, while in other embodiments, the conductor may be deposited directly on the core substrate 103.

In some embodiments, the one or more heat conduits 144, the one or more fluid cooling channels 142, or a combination thereof may be formed in the core substrate 103 during the preparation of the core substrate 103 at S410. In some embodiments, the one or more heat conduits 144, the one or more fluid cooling channels 142, or a combination thereof may be formed by first forming one or more openings within the core substrate 103, the openings may be formed using drilling, laser milling, etching, or any other suitable process, and combinations thereof. In some embodiments, the one or more heat conduits 144, the one or more fluid cooling channels 142, or a combination thereof may then be partially or completely filled using a thermal conductive material such as one or more layers of metals, carbides or nitrides. In some embodiments, the one or more fluid cooling channels 142 may be partially formed within the core substrate 103, and may include one or more parts formed on the core substrate 103. For example, an open channel may be formed within the core substrate 103, with a lid placed upon the supporting substrate 101 to cover the open channel. In other embodiments, any suitable technique may be used to form the one or more fluid cooling channels 142 within the supporting substrate 101. In some embodiments, the one or more heat conduits 144 may be formed to a specified depth within the core substrate 103 to couple with embedded devices, while in other embodiments, the depth may be larger or smaller. In some embodiments, the one or more heat conduits 144 and the one or more fluid cooling channels 142 may be formed within the same layer of the core substrate 103. In other embodiments the one or more fluid cooling channels 142 may be formed above or below the one or more heat conduits 144.

FIG. 3B depicts S420 in the process of FIG. 4 where one or more attachment location 301 are formed in the supporting substrate 101. In some embodiments, the one or more attachment location 301 may be formed using a variety of techniques, such as laser milling, drilling, etching, or any other suitable process either alone or in combination. In some embodiments, the one or more attachment location 301 may be formed to a depth intersecting the one or more heat conduits 144, while in other embodiments, the depth may be larger or smaller. In some embodiments, the one or more attachment location 301 may be formed to a uniform depth, while in other embodiments, the one or more attachment location 301 may vary in depth within each cavity, between each cavity, or a combination thereof. In some embodiments, the one or more attachment location 301 may be formed to a depth such that one or more of the first embedded circuit 108, the first multi-device package 102 and the second multi-device package 122 may be placed within a corresponding cavity such that a surface of one or more of the first embedded circuit 108, the first multi-device package 102 and the second multi-device package 122 may be coplanar with a surface of the core substrate 103, while in other embodiments, the surface of one or more of the first embedded circuit 108, the first multi-device package 102 and the second multi-device package 122 may be above or below a corresponding surface of the core substrate 103.

FIG. 3C depicts S430 in the process of FIG. 4 where the attachment layer 109 is deposited within the one or more attachment location 301. In some embodiments, the attachment layer 109 may be formed from an adhesive material such as a resin or epoxy, a metal layer, a dielectric material, and any other suitable material to form one or more layers to allow the one or more of the first embedded circuit 108, the first multi-device package 102 and the second multi-device package 122 to attach to the core substrate 103. In some embodiments, the attachment layer 109 may formed using a process such as CVD, PVD, ALD, or any other suitable process. In some embodiments, the attachment layer 109 may be the same material in each of the one or more attachment location 301, while in other embodiments, the material of the attachment layer 109 may vary between the one or more attachment location 301. In some embodiments, the attachment layer 109 may be formed to a uniform depth in each of the one or more attachment location 301, while in some embodiments, the depth may vary within each of the one or more attachment location 301, or the depth may vary between each of the one or more attachment location 301.

FIG. 3D depicts S440 in the process of FIG. 4 where the first embedded circuit 108, the first multi-device package 102 and the second multi-device package 122 are placed on the attachment layer 109 within the one or more attachment location 301. In some embodiments, the first embedded circuit 108, the first multi-device package 102 and the second multi-device package 122 may be placed such that a surface of one or more of the first embedded circuit 108, the first multi-device package 102 and the second multi-device package 122 may be coplanar with a surface of the core substrate 103, while in other embodiments the surface of the first embedded circuit 108, the first multi-device package 102 and the second multi-device package 122 may be above or below a corresponding surface of the core substrate 103. In some embodiments, the first embedded circuit 108 may comprise a logic circuit, a voltage regulation module, or a capacitor, while in other embodiments the first embedded circuit 108 may be formed using a semiconductor substrate, such as a silicon die. In some embodiments, the first embedded circuit 108, the first multi-device package 102 and the second multi-device package 122 may have the attachment layer 109 form a bond between one or more of the first embedded circuit 108, the first multi-device package 102 and the second multi-device package 122 and the core substrate 103. In some embodiments, the supporting substrate 101 may be further treated to bond one or more of the first embedded circuit 108, the first multi-device package 102 and the second multi-device package 122 to the core substrate 103, and may include the use of thermal energy or radiation energy to form a bond, such as by curing an epoxy or resin within the attachment layer 109.

FIG. 3E depicts S450 in the process of FIG. 4 where the upper RDL 112 and the lower RDL 114 are formed on the core substrate 103. The upper RDL 112 and the lower RDL 114 may include one or more layers including a series of pads, bumps, vias, through-vias, traces, and other forms of connection for redistributing signals. In some embodiments, the upper RDL 112 and the lower RDL 114 may be formed directly on a surface of the core substrate 103, while in some embodiments one or more build up layers may be formed to create a planar surface which the upper RDL 112 and the lower RDL 114 may be formed upon. In some embodiments, the buildup layer may include one or more materials including molding compounds, resins, epoxies, dielectric material, and other suitable materials for use with the core substrate 103. In some embodiments, the upper RDL 112 may be formed over the one or more attachment location 301, and may be coupled to the first embedded circuit 108, the first multi-device package 102 and the second multi-device package 122. In some embodiments, the upper RDL 112 and the lower RDL 114 may be formed using a variety of techniques to form and pattern conductive layers, including the deposition of one or more materials using PVD, CVD, ALD, or other suitable techniques. The materials may be further patterned using techniques such as lithography, etching, grinding, milling, ablation, to selectively remove portions of the materials, while in other embodiments, techniques such as using a photoresist mask may be used to selectively deposit materials. In some embodiments, the materials may include conductive materials such as metals, as well as dielectric materials such as nitrides and oxides. In some embodiments, the upper RDL 112 and the lower RDL 114 may be formed in parallel, while in other embodiments, the upper RDL 112 and the lower RDL 114 may be formed sequentially, or in a combination of parallel and sequential steps.

FIG. 3F depicts S460 in the process of FIG. 4 where the upper RDL 112 has one or more conductive elements prepared to form bumps, vias, grooves for coupling the first surface compute device 111 and the second surface compute device 113. Additionally, at S460, the substrate interconnection 140 may be formed upon the lower RDL 114. In some embodiments, the substrate interconnection 140 may include a conductive interconnection, a dielectric interconnection, or a hybrid interconnection. In some embodiments, a conductive interconnection may include pads, bumps, microbumps, pillars, balls, ball grids, microball arrays, and other forms such as C4 bumps, alone or in combination. In some embodiments, a dielectric interconnection may include a dielectric material such as silicon dioxide, resins, adhesives, and epoxies, alone or in combination. In some embodiments, the dielectric material may take the form of an underfill and be introduced between a card and the supporting substrate 101 in conjunction with a conductive interconnection, and may form a hybrid connection between the card and the supporting substrate 101. In some embodiments, the substrate interconnection 140 may electrically connect the supporting substrate 101 to further substrate such as an interposer, additional substrate, card, board, or some combination thereof. In some embodiments, the substrate interconnection 140 may be fully formed at S460, placing the supporting substrate 101 on the further substrate, while in other embodiments, the substrate interconnection 140 may be only partially formed at S460, such as forming a conductive ball grid array suitable for later placing of the supporting substrate 101 on the further substrate.

FIG. 4G depicts S470 in the process of FIG. 4 where the first surface compute device 111 and the second surface compute device 113 may be placed on the supporting substrate 101, upon the upper RDL 112. In some embodiments, the first surface compute device 111 and the second surface compute device 113 may be placed upon the upper RDL 112 using one or more conductive connections and one or more dielectric bonds. The one or more conductive connections may include pads, bumps, microbumps, pillars, balls, ball grids, microball arrays, and other forms such as C4 bumps, alone or in combination. The one or more dielectric bonds may include a dielectric material or adhesive between the first surface compute device 111 or the second surface compute device 113 and the upper RDL 112, such as an epoxy, a resin, or other suitable material. In some embodiments, the one or more dielectric bonds may be formed using an underfill technique and inserted between the first surface compute device 111 or the second surface compute device 113 and the upper RDL 112 and around the one or more conductive connections. In some embodiments, the one or more conductive connections and the one or more dielectric bonds may combine to form a hybrid bond between the first surface compute device 111 or the second surface compute device 113 and the supporting substrate 101.

FIG. 3H depicts S480 in the process of FIG. 4 where the conductive lid 132 is coupled to the supporting substrate 101 via the upper RDL 112 and the first surface compute device 111 and the second surface compute device 113. In some embodiments, the conductive lid 132 may be coupled directly to one or more of the upper RDL 112, the first surface compute device 111 and the second surface compute device 113, while in other embodiments, one or more intermediate layers may be between the conductive lid 132 and the first surface compute device 111 and the second surface compute device 113. In some embodiments, the one or more intermediate layers may include a thermally conductive material, such as a thermal paste. In some embodiments, the conductive lid 132 may be formed of a thermal conductive material such as copper or other suitable metals like aluminum. In some embodiments, the conductive lid 132 may be permanently attached to the supporting substrate 101, while in other embodiments the conductive lid 132 may be removably attached to the supporting substrate 101. In some embodiments, the conductive lid 132 may include one or more thermal conductive structures, including heat exchangers, fins, and heat sinks.

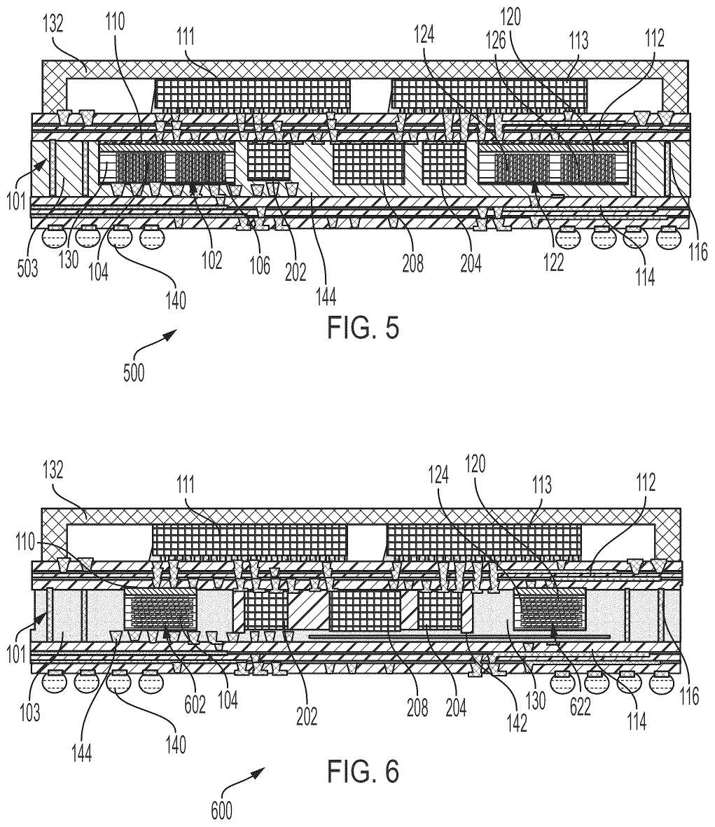

FIG. 5 depicts a cross-section view of an example embodiment of a third device package architecture 500, the third device package architecture 500 differing from the second device package architecture 200 of FIG. 2A by replacing the core substrate 103 with an organic substrate 503. Furthermore, the third device package architecture 500, being an organic substrate, may lack the one or more fluid cooling channels 142 and the one or more heat conduits 144 of the first device package architecture 100. The organic substrate 503 may include one or more layers of organic materials, including polymers.

FIG. 6 depicts a cross-section view of an example embodiment of a fourth device package architecture 600, the fourth device package architecture 600 differing from the second device package architecture 200 of FIG. 2A by using a first single device package 602 and a second single device package 622 in place of the first multi-device package 102 and the second multi-device package 122. In the first single device package 602, only the first compute device 104 is present, while in the second single device package 622, only the third compute device 124 is present. As such, the first support base 110 and the second support base 120 may provide less functions, such as reducing the routing logic, and in some embodiments might provide additional functions such as expanded buffering.

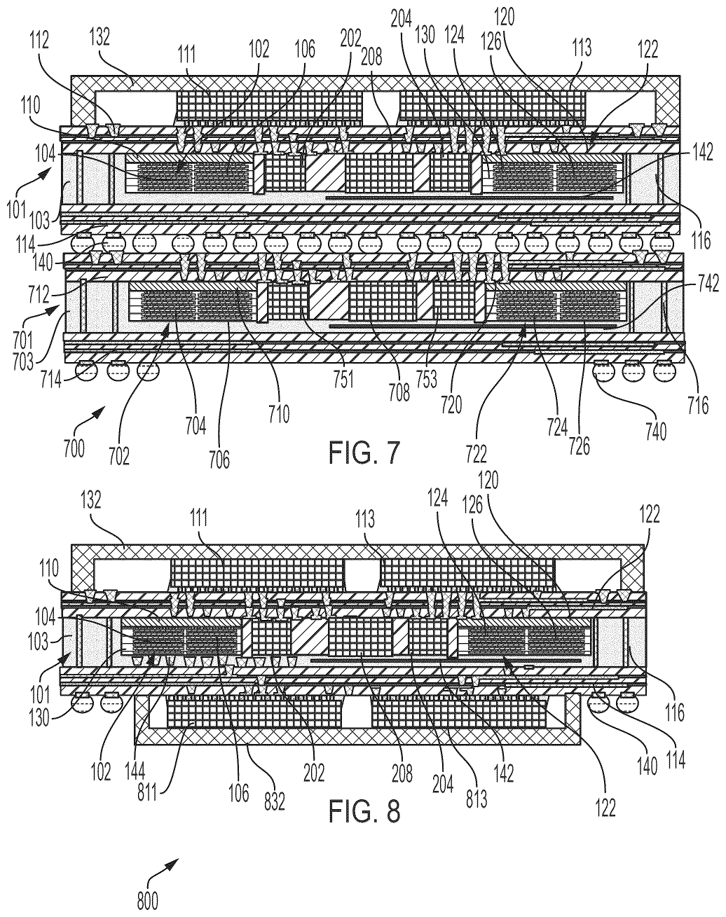

FIG. 7 depicts a cross-section view of an example embodiment of a fifth device package architecture 700, the fifth device package architecture 700 differing from the second device package architecture 200 of FIG. 2A by placing the supporting substrate 101 on a second supporting substrate 701. The second supporting substrate 701 may be formed similar to the supporting substrate 101, including a second core substrate 703 with a third multi-device package 702 and a fourth multi-device package 722. The third multi-device package 702 may include fifth compute device 704 and sixth compute device 706 coupled to a third supporting base 710; while the fourth multi-device package 722 may include seventh compute device 724 and eighth compute device 726 coupled to a fourth supporting base 720. The compute devices and supporting bases may be as previously described. Similarly, a secondary connecting element 708 may be similar to the first connecting element 208, and the fourth embedded circuit 751 and fifth embedded circuit 753 may be similar to the second embedded circuit 202 and the third embedded circuit 204. The second supporting substrate 701 may have a second upper RDL 712 coupled to the substrate interconnections 140 and thus couple to the supporting substrate 101 and the elements therein. A second lower RDL 714 may, like the lower RDL 114, be coupled using one or more second vias 716 to the second upper RDL 712, and be further coupled to a supporting card or board using second interconnections 740. Furthermore, additional heat conduits may be formed within the second supporting substrate 701 similar to the heat conduits of the supporting substrate 101, and likewise may couple to a second set of fluid cooling channels 742. While not shown in FIG. 7, the one or more heat conduits 144 may be present within the supporting substrate 101.

FIG. 8 depicts a cross-section view of an example embodiment of a sixth device package architecture 800, the sixth device package architecture 800 differing from the second device package architecture 200 of FIG. 2A by placing a second set of surface compute devices on the bottom of the supporting substrate 101. A third surface compute device 811 and a fourth surface compute device 813 may be attached on bottom of the supporting substrate 101 and coupled via the lower RDL 114 to the rest of the elements of the sixth device package architecture 800. A second conductive lid 832 may likewise be placed on the bottom of the supporting substrate 101, and coupled to the lower RDL 114, the third surface compute device 811 and the fourth surface compute device 813 similarly to the conductive lid 132. The sixth device package architecture 800 may, in some embodiments, have the substrate interconnections 140 positioned to allow the supporting substrate 101 to be placed on posts or pillars to allow the second conductive lid 832 to thermally transfer heat from the supporting substrate 101 to the surrounding environment.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a substrate having a first attachment location and a second attachment location;
a first multi-device package located within the first attachment location;
a first embedded circuit located within the second attachment location; and
a first compute device located on the substrate and at least partially over the first attachment location and the second attachment location.

2. The device of claim 1, further comprising a second compute device located on the substrate at least partially over the second attachment location, wherein the second compute device is electrically connected to the first compute device by the first embedded circuit.

3. The device of claim 1, wherein the first multi-device package includes at least one selected from the group consisting of a memory device and a processing device.

4. The device of claim 1, wherein a redistribution layer is arranged between the first compute device and the first multi-device package.

5. The device of claim 1, wherein the substrate comprises at least one selected from the group consisting of glass and silicon.

6. The device of claim 1, wherein the first compute device comprises an integrated circuit.

7. The device of claim 1, further comprising:
a fluid cooling channel formed within the substrate; and
a heat conduit formed between the first attachment location and a surface of the substrate,
wherein the heat conduit thermally couples the first multi-device package to the fluid cooling channel.

8. The device of claim 1, further comprising a third attachment location; and
a second multi-device package located within the third attachment location,
wherein the second multi-device package is coupled to the first multi-device package via the first embedded circuit.

9. A system comprising:
a substrate having a first side and a second side opposite the first side, the first side having a first attachment location and a second attachment location;
a first multi-device package at least partially within the first attachment location;
a first connecting element at least partially within the second attachment location;
a first compute device located on the first side of the substrate; and
a first heat conduit within the substrate, the first heat conduit extending from the second side to the first attachment location.

10. The system of claim 9, further comprising a second compute device located on the first side of the substrate,
wherein the second compute device is coupled to the first compute device via the first connecting element with the first connecting element at least partially within the second attachment location.

11. The system of claim 9, further comprising an attachment layer between the first heat conduit and the first multi-device package.

12. The system of claim 9, further comprising:
a second heat conduit within the substrate, wherein the second heat conduit extends from the second side to the second attachment location; and
an attachment layer between the second heat conduit and the first connecting element.

13. The system of claim 9, further comprising a fluid cooling channel within the substrate and thermally coupled to the first heat conduit.

14. The system of claim 9, further comprising a redistribution layer arranged between the first compute device and the first multi-device package.

15. The system of claim 9, wherein the first compute device is placed at least partially over the first attachment location and the second attachment location.

16. A method comprising:
forming a first attachment location and a second attachment location within a first side of a substrate;
placing a first multi-device package at least partially within the first attachment location;
placing a first embedded circuit at least partially within the second attachment location;
forming a redistribution layer on the first side of the substrate;
placing a first compute device on the redistribution layer, the first compute device electrically connected to the first multi-device package and the first embedded circuit; and
placing a second compute device on the redistribution layer, the second compute device electrically connected to the first compute device via the first embedded circuit.

17. The method of claim 16, further comprising preparing the substrate including at least one of forming a heat conduit, forming a liquid cooling channel and forming a through-substrate via.

18. The method of claim 16, further comprising placing a conductive lid over at least one of the first compute device, the second compute device and the redistribution layer.

19. The method of claim 16, wherein the first multi-device package comprises at least one of a processing device and a memory device.

20. The method of claim 16, wherein forming the first attachment location and the second attachment location within the first side of the substrate comprises laser milling a glass substrate.
